(19) United States
(12) Patent Application Publication
(10) Pub. No.: US 2024/0088006 A1
(43) Pub. Date: Mar. 14, 2024

(54) SEMICONDUCTOR PACKAGE

(71) Applicant: Samsung Electronics Co., Ltd., Suwon-si (KR)

(72) Inventors: Sangcheon PARK, Suwon-si (KR); Dongwoo KANG, Suwon-si (KR); Unbyoung KANG, Suwon-si (KR); Soohwan LEE, Suwon-si (KR); Hyunchul JUNG, Suwon-si (KR); Youngkun JEE, Suwon-si (KR)

(73) Assignee: Samsung Electronics Co., Ltd., Suwon-si (KR)

(21) Appl. No.: 18/317,521

(22) Filed: May 15, 2023

(30) Foreign Application Priority Data
Sep. 13, 2022 (KR) 10-2022-0115102

(51) Int. Cl. H01L 23/498; H01L 23/00; H01L 23/538

(52) U.S. Cl. CPC H01L 23/49827; H01L 23/5389; H01L 24/06; H01L 24/32; H01L 2224/0401; H01L 2224/06515; H01L 2224/32235; H01L 2924/1434

(57) ABSTRACT

Provided is a semiconductor package including a substrate including a first surface and a second surface opposite to the first surface, a connecting circuit arranged on the first surface of the substrate, a through silicon via (TSV) structure penetrating the substrate, a first passivation layer arranged on the connecting circuit, a second passivation layer arranged on the second surface, a first bumping pad arranged inside the first passivation layer, and a second bumping pad arranged inside the second passivation layer, wherein the first bumping pad includes a first pad plug, and a first seed layer surrounding a lower surface and sidewalls of the first pad plug, wherein the second bumping pad includes a second pad plug, and a second seed layer surrounding an upper surface and sidewalls of the second pad plug, and wherein the first seed layer and the second seed layer include materials having different reactivities to water.

### CROSS-REFERENCE TO RELATED APPLICATION

This application is based on and claims priority under 35 U.S.C. § 119 to Korean Patent Application No. 10-2022-0115102, filed on Sep. 13, 2022 in the Korean Intellectual Property Office, the disclosure of which is incorporated by reference herein in its entirety.

### BACKGROUND

The inventive concepts relate to semiconductor packages. More particularly, the inventive concepts relate to semiconductor packages including a through silicon via (TSV).

It is required that the storage capacity of a semiconductor chip increases, and at the same time, that a semiconductor package including the semiconductor chip be thin and light. In addition, there is a trend in research to include semiconductor chips having various functions in a semiconductor package and to drive the semiconductor chips faster. According to this trend, there is an increasing need for miniaturization and multi-functionalization of semiconductor chips used in electronic components.

### SUMMARY

The inventive concepts provide semiconductor packages having improved reliability and including a through silicon via (TSV).

According to an aspect of the inventive concepts, there is provided a semiconductor package including a substrate including a first surface and a second surface opposite to the first surface, a connecting circuit on the first surface of the substrate, a through silicon via (TSV) structure penetrating the substrate, a first passivation layer on the connecting circuit, a second passivation layer on the second surface of the substrate, a first bumping pad inside the first passivation layer, and a second bumping pad inside the second passivation layer, wherein the first bumping pad includes a first pad plug, and a first seed layer surrounding a lower surface and sidewalls of the first pad plug, wherein the second bumping pad includes a second pad plug, and a second seed layer configured to surround an upper surface and sidewalls of the second pad plug, and

wherein the first seed layer and the second seed layer include materials having different reactivities to water.

According to another aspect of the inventive concepts, there is provided a semiconductor package including a substrate including a first surface and a second surface opposite to the first surface, an interlayer insulating layer on the first surface of the substrate, a through silicon via (TSV) structure penetrating the substrate and the interlayer insulating layer, a connecting circuit on the interlayer insulating layer, the connecting circuit including a TSV connecting via that is electrically connected to the TSV structure, a first passivation layer on the connecting circuit, a second passivation layer on the second surface of the substrate, a first bumping pad inside the first passivation layer, and a second bumping pad inside the second passivation layer, wherein the first bumping pad includes a first pad plug, a first seed layer surrounding a lower surface and sidewalls of the first pad plug, and a first barrier layer surrounding a lower surface and outer walls of the first seed layer, wherein the second bumping pad includes a second pad plug, a second seed layer surrounding a lower surface and sidewalls of the second pad plug, and a second barrier layer surrounding a lower surface and outer walls of the second seed layer, and wherein reactivity to water of the second seed layer is less than reactivity to water of the first seed layer.

According to another aspect of the inventive concepts, there is provided a semiconductor package including a substrate including a first surface and a second surface opposite to the first surface, a transistor on the first surface of the substrate, an interlayer insulating layer on the first surface of the substrate, and covering the transistor, a through silicon via (TSV) structure penetrating the substrate and the interlayer insulating layer, a connecting circuit on the interlayer insulating layer, the connecting circuit including a TSV connecting via that is electrically connected to the TSV structure, a first passivation layer on the connecting circuit, a second passivation layer on the second surface of the substrate, a first bumping pad inside the first passivation layer, and a second bumping pad inside the second passivation layer, wherein the first bumping pad includes a first pad plug, a first seed layer surrounding a lower surface and sidewalls of the first pad plug, and a first barrier layer surrounding a lower surface and outer walls of the first seed layer, wherein the second bumping pad includes a second pad plug, a second seed layer surrounding a lower surface and sidewalls of the second pad plug, and a second barrier layer surrounding a lower surface and outer walls of the second seed layer, wherein the first seed layer and the second seed layer include different materials, and wherein reactivity to water of the second seed layer is less than reactivity to water of the first seed layer.

### BRIEF DESCRIPTION OF THE DRAWINGS

Example embodiments will be more clearly understood from the following detailed description taken in conjunction with the accompanying drawings in which:

FIG. 1 is a cross-sectional view of a semiconductor package according to an example embodiment;

FIG. 2 is an enlarged cross-sectional view of region II in FIG. 1, according to an example embodiment;

FIG. 3 is a cross-sectional view of a semiconductor package according to another example embodiment;

FIG. 4 is an enlarged cross-sectional view of region IV in FIG. 3, according to an example embodiment;

FIGS. 5A through 5L are cross-sectional views illustrating a method of manufacturing a semiconductor package, according to an example embodiment;

FIG. 6 is a cross-sectional view of a semiconductor package according to another example embodiment;

FIG. 7 is a conceptual diagram of a memory module according to an example embodiment;

FIG. 8 is a conceptual diagram of a semiconductor module according to an example embodiment;

FIG. 9 is a conceptual diagram of an electronic system according to an example embodiment; and

FIG. 10 is a conceptual diagram of an electronic system according to another example embodiment.

### DETAILED DESCRIPTION

Hereinafter, some example embodiments of the inventive concepts are described in detail with reference to the accompanying drawings. Identical reference numerals are used for the same constituent elements in the drawings, and duplicate descriptions thereof are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

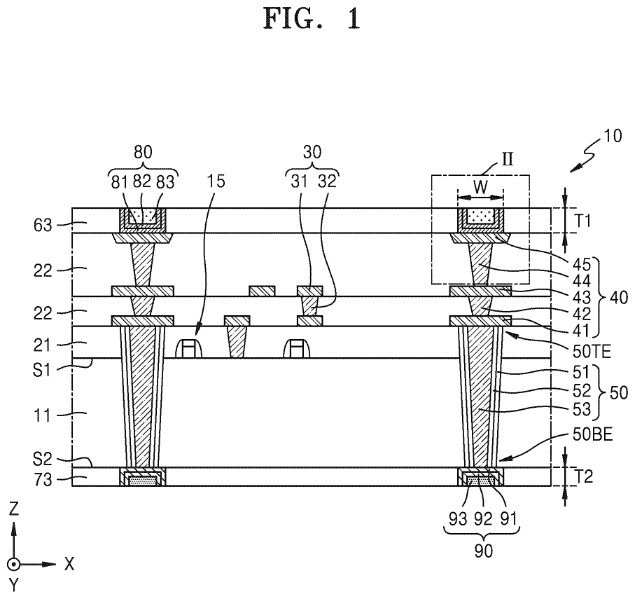

FIG. 1 is a cross-sectional view of a semiconductor package 10 according to an example embodiment.

Referring to FIG. 1, the semiconductor package 10 may include a transistor 15 arranged on a first surface S1 of a substrate 11, an internal circuit 30, a connecting circuit 40, a first interlayer insulating layer 21, a second interlayer insulating layer 22, a through silicon via (TSV) structure 50 penetrating the substrate 11 and the first interlayer insulating layer 21, a first bumping pad 80 arranged on the first surface S1 of the substrate 11 to be vertically aligned to the TSV structure 50, and a second bumping pad 90 arranged on a second surface S2 of the substrate 11 to be vertically aligned with the TSV structure 50.

According to some example embodiments, the substrate 11 may include a semiconductor material such as a Group IV semiconductor material, a Group III-V semiconductor material, and a Group II-VI semiconductor material. The Group IV semiconductor material may include, for example, silicon (Si), germanium (Ge), or Si—Ge. The Group III-V semiconductor material may include, for example, gallium arsenide (GaAs), indium phosphorus (InP), GaP, InAs, In tin (InSb), or InGaAs. The Group II-VI semiconductor material may include, for example, telluride zinc (ZnTe), or cadmium sulfide (CdS).

The substrate 11 may include a p-type semiconductor substrate. For example, the substrate 11 may include a p-type silicon substrate. In some example embodiments, the substrate 11 may include a p-type bulk substrate with a p-type or an n-type epitaxial layer grown thereon. In some example embodiments, the substrate 11 may include an n-type bulk substrate with a p-type or an n-type epitaxial layer grown thereon. In some example embodiments, the substrate 11 may include an organic plastic substrate.

The substrate 11 may include the first surface S1 and the second surface S2 opposite to the first surface S1. The first surface S1 of the substrate 11 may be the front side surface of the substrate 11, and the second surface S2 of the substrate 11 may be the back side surface of the substrate 11.

The transistor 15 may be arranged on the first surface S1 of the substrate 11. The transistor 15 may include NMOS or PMOS, and may constitute a logic circuit or a switching element.

The first interlayer insulating layer 21 may cover the transistor 15 and surround sidewalls of the TSV structure 50. The first interlayer insulating layer 21 may include at least one of a silicon oxide (SiO) layer, a silicon carbonized oxide (SiCO) layer, a silicon nitride (SiN) layer, a silicon carbonized nitride (SiCN) layer, or another insulating material layer.

The internal circuit 30 may include multi-layered internal wirings 31 extending horizontally and multi-layered internal vias 32 extending in a vertical direction (Z direction). The internal circuit 30 may be electrically connected to the substrate 11 and the transistor 15. The internal wirings 31 and the internal vias 32 may include metals. Each of the internal vias 32 may have a tapered shape, in which an upper width is less than a lower width. In another example embodiment, each of the internal vias 32 may have a tapered shape, in which the lower width is less than the upper width. In another example embodiment, although not illustrated in FIG. 1, the multi-layered internal wirings 31 may have a tapered shape, in which the upper width is less than the lower width. In another example embodiment, the multi-layered internal wirings 31 may have a tapered shape, in which the lower width is less than the upper width.

According to an example embodiment, a direction in parallel with a main surface of the substrate 11 may be defined as a horizontal direction (X direction and/or Y direction), and a direction perpendicular to the horizontal direction (X direction and/or Y direction) may be defined as the vertical direction (Z direction). In addition, in FIGS. 1 through 5L, an upper surface of a component except for a second passivation layer 73 may mean the farthest surface from the second passivation layer 73 in the vertical direction (Z direction), and a lower surface of a component except for the second passivation layer 73 may mean a surface opposite to the upper surface of the component. The upper surface of the second passivation layer 73 may mean a surface in contact with the second surface S2 of the substrate 11, and the lower surface of the second passivation layer 73 may mean a surface opposite to the upper surface of the second passivation layer 73.

The connecting circuit 40 may electrically connect the TSV structure 50 to the first bumping pad 80. The connecting circuit 40 may include a lower TSV pad 41, a lower TSV connecting via 42, a TSV connecting wiring 43, an upper TSV connecting via 44, and an upper TSV pad 45. The upper TSV pad 45 may include, for example, a TSV input/output (IO) pad. The lower TSV pad 41 may be formed on the first interlayer insulating layer 21 to be in contact with an upper end 50TE of the TSV structure 50. The TSV connecting wiring 43 may be arranged at the same vertical level as at least one layer of the internal wirings 31. The upper TSV pad 45 may be arranged at the highest vertical level of the internal circuit 30 and the connecting circuit 40. The lower TSV connecting via 42 may electrically connect the lower TSV pad 41 to the TSV connecting wiring 43, and the upper TSV connecting via 44 may electrically connect the TSV connecting wiring 43 to the upper TSV pad 45. The upper TSV pad 45 may be embedded in the second interlayer insulating layer 22. For example, an upper surface of the upper TSV pad 45 may be coplanar with an upper surface of the second interlayer insulating layer 22.

For example, each of the lower TSV connecting via 42, the upper TSV connecting via 44, and/or the upper TSV pad 45 may have a tapered shape, in which the upper width is less than the lower width. In another example embodiment, each of the lower TSV connecting via 42, the upper TSV connecting via 44, and/or the upper TSV pad 45 may have a tapered shape, in which the lower width is less than the upper width. In another example embodiment, although not illustrated in FIG. 1, the lower TSV pad 41 and/or the TSV connecting wiring 43 may have a tapered shape, in which the upper width is less than the lower width. In another example embodiment, the lower TSV pad 41 and/or the TSV connecting wiring 43 may have a tapered shape, in which the lower width is less than the upper width.

The internal circuit 30 and the connecting circuit 40 may include a conductor. For example, the internal circuit 30 and the connecting circuit 40 may include metal (e.g., tungsten (W), copper (Cu), aluminum (Al), nickel (Ni), or titanium (Ti)), a metal compound (e.g., titanium nitride (TiN) or tungsten nitride (WN)), or metal silicide (e.g., titanium silicide (TiSi), tungsten silicide (WSi), cobalt silicide (CoSi), or nickel silicide (NiSi)). In another example embodiment, the upper TSV pad 45 may include aluminum to allow a probe or the like of a test facility to be in contact therewith. The second interlayer insulating layer 22 may cover the internal circuit 30 and the connecting circuit 40, or may surround sidewalls of the connecting circuit 40.

The TSV structure 50 may penetrate the first interlayer insulating layer 21 and the substrate 11 in the vertical direction (Z direction). The TSV structure 50 may include a TSV liner 51, a TSV barrier layer 52, and a TSV plug 53. The TSV liner 51 may surround the TSV barrier layer 52. The TSV barrier layer 52 may surround the TSV plug 53. For example, the TSV liner 51 may include silicon oxide, the TSV barrier layer 52 may include TiN or tantalum nitride (TaN), and the TSV plug 53 may include Cu. An upper surface of the TSV structure 50 and an upper surface of the first interlayer insulating layer 21 may be coplanar with each other. The TSV plug 53 may have a tapered shape, in which an upper width is less than a lower width. In another example embodiment, the TSV plug 53 may have a tapered shape, in which a lower width is less than an upper width.

The semiconductor package 10 may further include a first passivation layer 63 arranged on the second interlayer insulating layer 22. The first passivation layer 63 may include silicon nitride or polyimide. The first bumping pad 80 may be arranged inside the first passivation layer 63. Although FIG. 1 illustrates that the semiconductor package 10 includes one first passivation layer 63, the semiconductor package 10 may include a plurality of first passivation layers 63 including a single material or including different materials from each other. The first passivation layer 63 may have a first thickness T1 in the vertical direction (Z direction). The range of a first thickness T1 may be about 0.3 micrometers to about 3 micrometers.

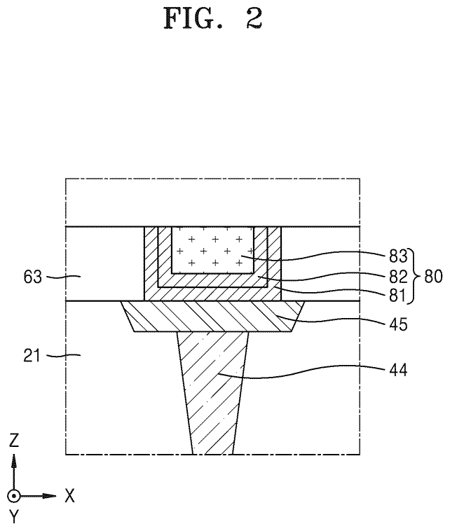

The first bumping pad 80 may be formed on the upper TSV pad 45. The first bumping pad 80 may include a first barrier layer 81, a first seed layer 82, and a first pad plug 83. A detailed description of the first bumping pad 80 is given below with reference to FIG. 2.

The first barrier layer 81 may include TiN or TaN. The first seed layer 82 may include at least one of Ti, Cu, Ni, W, or alloys thereof, for example, titanium nickel (TiNi), titanium tungsten (TiW). In another example embodiment, the first barrier layer 81 and the first seed layer 82 may be formed as a single layer. The first pad plug 83 may include metal such as Cu or Ni. When the first seed layer 82 and the first pad plug 83 include the same metal, the first seed layer 82 and the first pad plug 83 may have a structure, in which the first seed layer 82 and the first pad plug 83 are connected to each other without a boundary surface therebetween. Further, an outer wall of the first barrier layer 81 may be in direct contact with the first passivation layer 63. In addition, an outer wall of the first seed layer 82 may be surrounded by the first barrier layer 81, and a sidewall of the first pad plug 83 may be surrounded by the first seed layer 82. The first barrier layer 81 may surround a lower surface and the outer walls of the first seed layer 82. The first seed layer 82 may surround the first pad plug 83. The first seed layer 82 may surround a lower surface and sidewalls of the first pad plug 83.

The semiconductor package 10 may include the second passivation layer 73 arranged on the second surface S2. Although it is illustrated in FIG. 1 that the semiconductor package 10 includes one second passivation layer 73, the semiconductor package 10 may include a plurality of second passivation layers 73 including a single material or including different materials from each other. The second passivation layer 73 may have a second thickness T2 in the vertical direction (Z direction). The range of the second thickness T2 may be about 0.2 micrometers to about 2 micrometers.

The second bumping pad 90 may be arranged on a lower end 50BE of the TSV structure 50. The second bumping pad 90 may include a second barrier layer 91, a second seed layer 92, and a second pad plug 93. The second barrier layer 91 may be in direct contact with the second passivation layer 73. For example, an outer wall of the second barrier layer 91 may be in direct contact with the second passivation layer 73. In addition, the second barrier layer 91 may surround the second seed layer 92. The second barrier layer 91 may surround a lower surface and outer walls of the second seed layer 92. The second seed layer 92 may surround the second pad plug 93. The second seed layer 92 may surround a lower surface and sidewalls of the second pad plug 93. The lower surface of the TSV structure 50 may be in contact with the second bumping pad 90 so that the TSV structure 50 is electrically connected to the second bumping pad 90. In addition, an upper surface of the second bumping pad 90 and/or a lower surface of the second bumping pad 90 may have a flat shape.

The second barrier layer 91 may include titanium nitride TiN or tantalum nitride TaN. The second seed layer 92 may include at least one of Ti, Cu, Ni, W, or alloys thereof, for example, TiNi, TiW. In another example embodiment, the second barrier layer 91 and the second seed layer 92 may be connected to each other, and may also be formed as a single layer. The second pad plug 93 may include metal such as Cu or Ni. When the second seed layer 92 and the second pad plug 93 include the same metal, the second seed layer 92 and the second pad plug 93 may have a structure, in which the second seed layer 92 and the second pad plug 93 are connected to each other without a boundary surface therebetween. The first seed layer 82 and the second seed layer 92 may include different materials from each other. For example, the second seed layer 92 may include a material having lower reactivity than the first seed layer 82. For example, reactivity to water of the first seed layer 82 and reactivity to water of the second seed layer 92 may be different from each other. For example, the second seed layer 92 may include a material having lower reactivity to water than the first seed layer 82. For example, the first seed layer 82 may include tantalum (Ta), and the second seed layer 92 may include titanium (Ti). The inventive concepts are not limited thereto, and the material included in the first seed layer 82 and the material included in the second seed layer 92 may be variously modified.

In an example embodiment, the first barrier layer 81 may include the same material as the first seed layer 82. In addition, the second barrier layer 91 may include the same material as the second seed layer 92. For example, the second barrier layer 91 may include a material having lower reactivity to water than the first barrier layer 81. For example, reactivity to water of the first barrier layer 81 and reactivity to water of the second barrier layer 91 may be different from each other. For example, the second barrier layer 91 may include a material having lower reactivity to water than the first barrier layer 81. For example, the first barrier layer 81 may include Ta, and the second barrier layer 91 may include Ti. The inventive concepts are not limited thereto, and the material included in the first barrier layer 81 and the material included in the second barrier layer 91 may be variously modified. In another example embodiment, the first barrier layer 81 may include a material different from a material of the first seed layer 82, and/or the second barrier layer 91 may include a material different from a material of the second seed layer 92.

The first passivation layer 63 and the second passivation layer 73 may include different materials. For example, the density of the first passivation layer 63 may be greater than that of the second passivation layer 73. For example, the resistance to the temperature of the first passivation layer 63 may be greater than that of the second passivation layer 73. According to some example embodiments of the inventive concepts, the resistance to the temperature of a component may be defined as a temperature, at which physical properties of the component do not change. For example, when the temperature, at which the physical properties of a component remain unchanged, is relatively high, the resistance to the temperature of the component may be relatively high, and when the temperature, at which the physical properties of a component remain unchanged, is relatively low, the resistance to the temperature of the component may be relatively low. Further, the dielectric constant of the first passivation layer 63 may be greater than that of the second passivation layer 73. As described above, the first thickness T1 of the first passivation layer 63 may be greater than the second thickness T2 of the second passivation layer 73.

Because the first passivation layer 63 is arranged on the connecting circuit 40, the first passivation layer 63 may be formed at a higher temperature than the second passivation layer 73 arranged on the second surface S2 of the substrate 11. Accordingly, the resistance to the temperature of the first passivation layer 63 may be greater than that of the second passivation layer 73.

The range of a horizontal width W, which is the width in the horizontal direction (X direction and/or Y direction) of the first bumping pad 80, may be about 2 micrometers to about 10 micrometers. The range of a horizontal width W, which is the width in the horizontal direction (X direction and/or Y direction) of the second bumping pad 90, may be about 2 micrometers to about 10 micrometers. Further, the thickness of the first bumping pad 80 in the vertical direction (Z direction) may be the same as or substantially similar to the first thickness T1 of the first passivation layer 63, and the thickness of the second bumping pad 90 in the vertical direction (Z direction) may be the same as or substantially similar to the second thickness T2 of the second passivation layer 73. In other words, the thickness of the first bumping pad 80 in the vertical direction (Z direction) may be greater than the thickness of the second bumping pad 90 in the vertical direction (Z direction).

FIG. 2 is an enlarged cross-sectional view of region II in FIG. 1, according to an example embodiment.

Referring to FIGS. 1 and 2, the semiconductor package 10 may include the first bumping pad 80 electrically connected to the upper TSV pad 45. The first bumping pad 80 may be arranged inside the first passivation layer 63.

The first bumping pad 80 may include the first barrier layer 81 in contact with an exposed surface of the upper TSV pad 45 and the surface of the first passivation layer 63, the first seed layer 82 on the first barrier layer 81, and the first pad plug 83 on the first seed layer 82.

An upper surface of the first bumping pad 80 may be coplanar with an upper surface of the first passivation layer 63. A lower surface of the first bumping pad 80 may be coplanar with a lower surface of the first passivation layer 63. Further, the upper surface of the first bumping pad 80 and/or the lower surface of the first bumping pad 80 may have a flat shape. The lower surface of the first bumping pad 80 may be in contact with the connecting circuit 40 to be electrically connected thereto. In other words, the first barrier layer 81 of the first bumping pad 80 may be in contact with the upper TSV pad 45 to be electrically connected thereto. In other words, the lower surface of the first bumping pad 80 may be coplanar with an upper surface of the upper TSV pad 45. Further, each of the uppermost surface of the first barrier layer 81, the uppermost surface of the first seed layer 82, and an upper surface of the first pad plug 83 may be coplanar with each other.

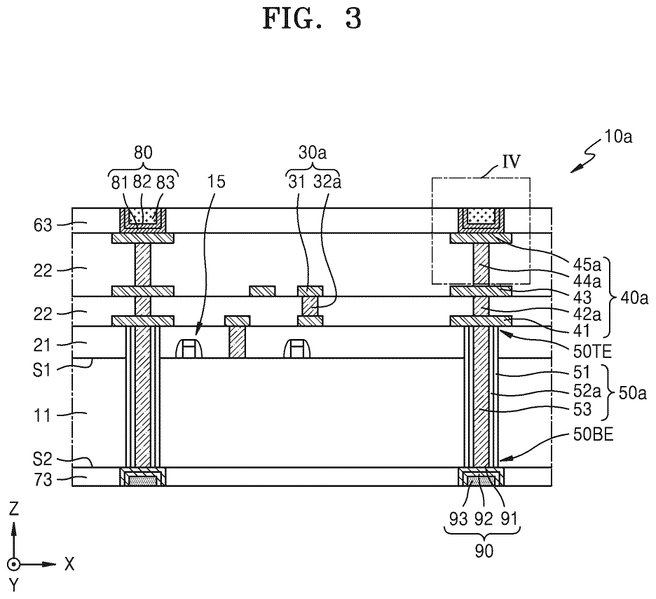

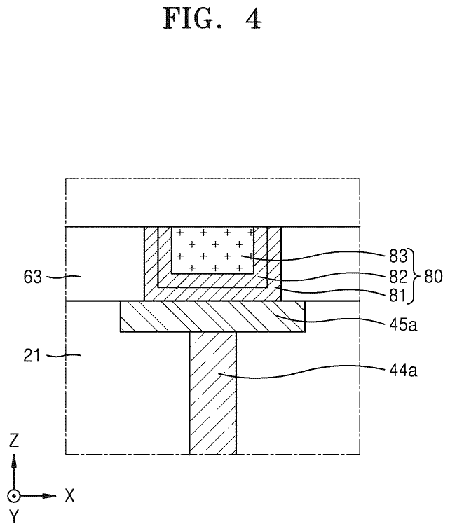

FIG. 3 is a cross-sectional view of a semiconductor package 10a according to an example embodiment, and FIG. 4 is an enlarged cross-sectional view of region IV in FIG. 3 according to an example embodiment.

Referring to FIGS. 3 and 4, the semiconductor package 10a may include the transistor 15 arranged on the first surface S1 of the substrate 11, an internal circuit 30a, a connecting circuit 40a, the first interlayer insulating layer 21, the second interlayer insulating layer 22, a TSV structure 50a penetrating the substrate 11 and the first interlayer insulating layer 21, the first bumping pad 80 arranged on the first surface S1 of the substrate 11 to be vertically aligned to the TSV structure 50a, and the second bumping pad 90 arranged on the second surface S2 of the substrate 11 to be vertically aligned with the TSV structure 50.

The internal circuit 30a may include multi-layered internal wirings 31 extending horizontally and multi-layered internal vias 32a extending in the vertical direction (Z direction). The internal circuit 30a may be electrically connected to the substrate 11 and the transistor 15. The internal wirings 31 and the internal vias 32a may include metals. Each of the internal vias 32a may have a rectangular shape having an upper width and a lower width, which are the same as or substantially similar to each other, and each of the internal vias 32a may have a rectangular shape, in which horizontal widths thereof are the same as or substantially similar to each other at different vertical levels.

The connecting circuit 40a may electrically connect the TSV structure 50a to the first bumping pad 80. The connecting circuit 40a may include the lower TSV pad 41, a lower TSV connecting via 42a, the TSV connecting wiring 43, an upper TSV connecting via 44a, and an upper TSV pad 45a. The upper TSV pad 45a may include, for example, the TSV I/O pad. The lower TSV pad 41 may be formed on the first interlayer insulating layer 21 to be in contact with an upper end 50TE of the TSV structure 50. The TSV connecting wiring 43 may be arranged at the same vertical level as one layer of the internal wirings 31. The upper TSV pad 45a may be arranged at the highest vertical level of the internal circuit 30 and the connecting circuit 40a. The lower TSV connecting via 42a may electrically connect the lower TSV pad 41 to the TSV connecting wiring 43, and the upper TSV connecting via 44a may electrically connect the TSV connecting wiring 43 to the upper TSV pad 45a. The upper TSV pad 45a may be embedded in the second interlayer insulating layer 22. For example, an upper surface of the upper TSV pad 45a may be coplanar with an upper surface of the second interlayer insulating layer 22. For example, a vertical cross-section of each of the lower TSV connecting via 42a, the upper TSV connecting via 44a, and/or the upper TSV pad 45a may have a rectangular shape, in which the width of an upper side thereof is the same as or substantially similar to the width of a lower side thereof, and horizontal widths thereof are the same or substantially constant regardless of vertical levels.

The TSV structure 50a may penetrate the first interlayer insulating layer 21 and the substrate 11 in the vertical direction (Z direction). The TSV structure 50a may include the TSV liner 51, the TSV barrier layer 52, and a TSV plug 53a. The TSV liner 51 may surround the TSV barrier layer 52. The TSV barrier layer 52 may surround the TSV plug 53a. For example, the TSV liner 51 may include silicon oxide, the TSV barrier layer 52 may include TiN or tantalum nitride (TaN), and the TSV plug 53a may include Cu. An upper surface of the TSV structure 50a and the upper surface of the first interlayer insulating layer 21 may be coplanar with each other. For example, a vertical cross-section of the TSV plug 53a may have a rectangular shape having an upper width and a lower width, which are generally similar to each other, and the vertical cross-section of the TSV plug 53a may have a rectangular shape, in which horizontal widths thereof are the same or substantially constant regardless of vertical levels.

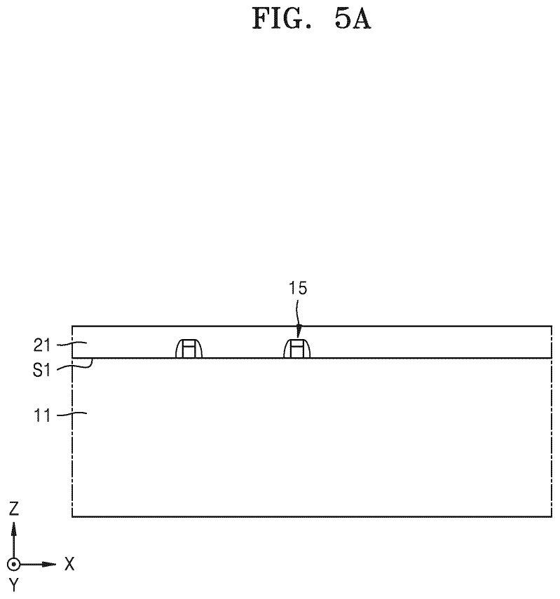

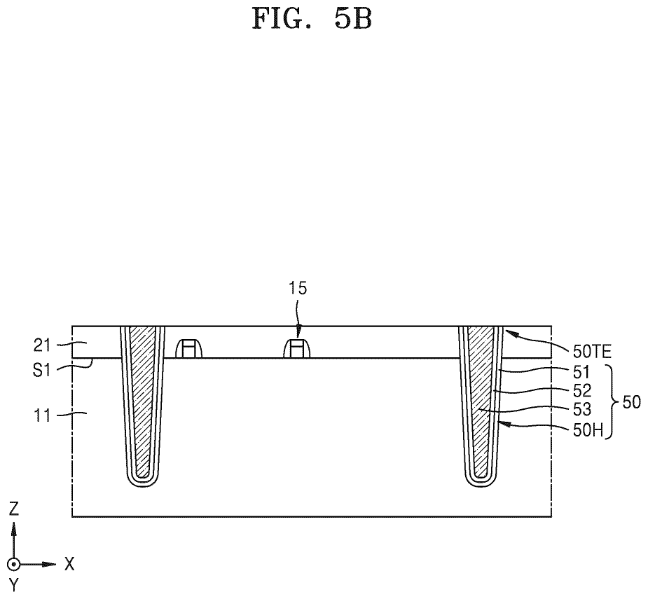

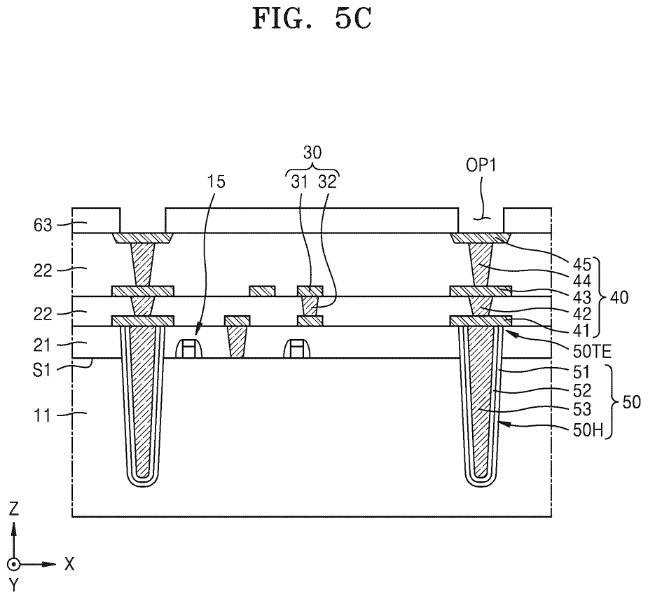

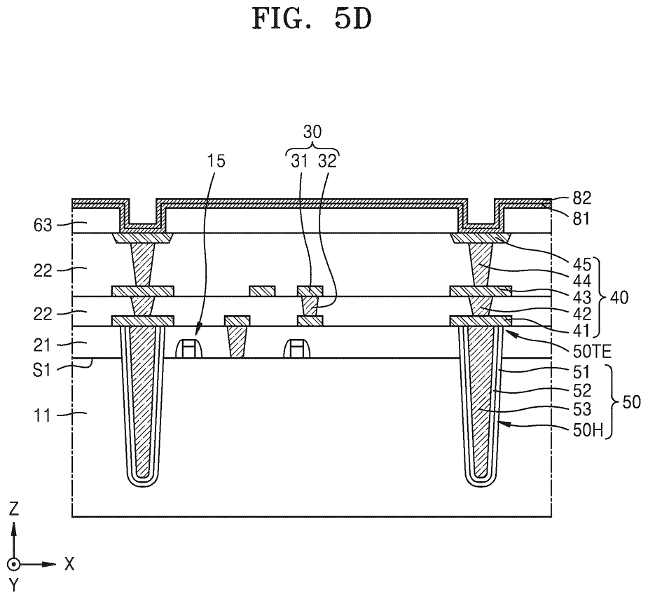

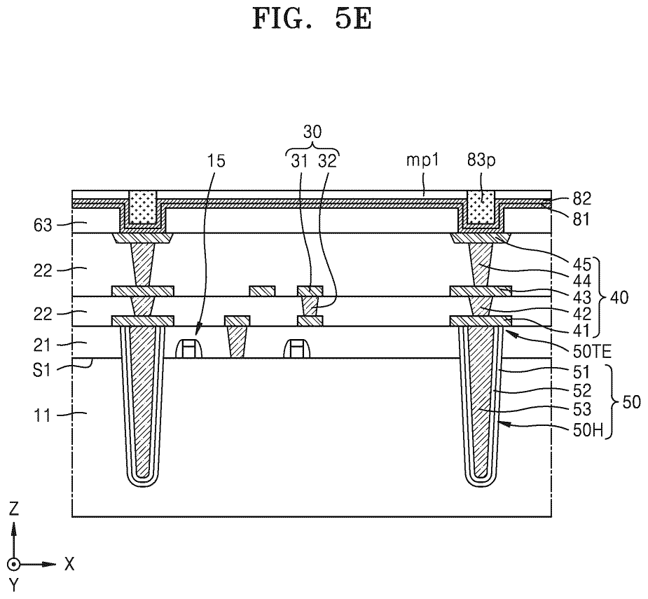

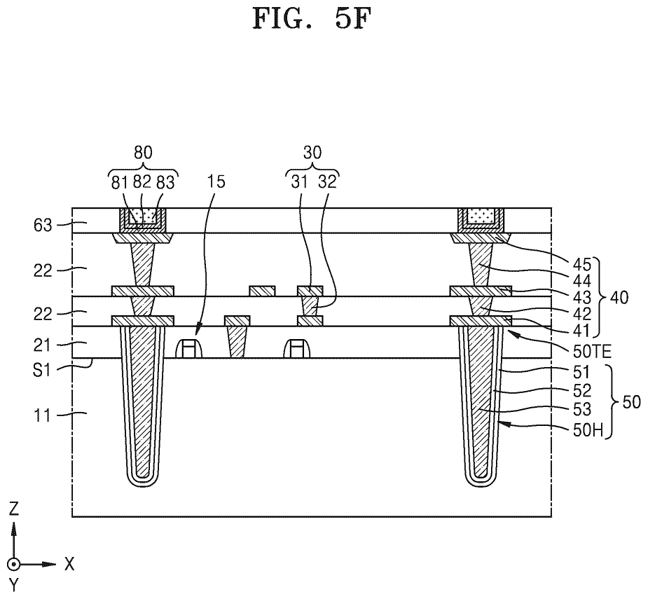

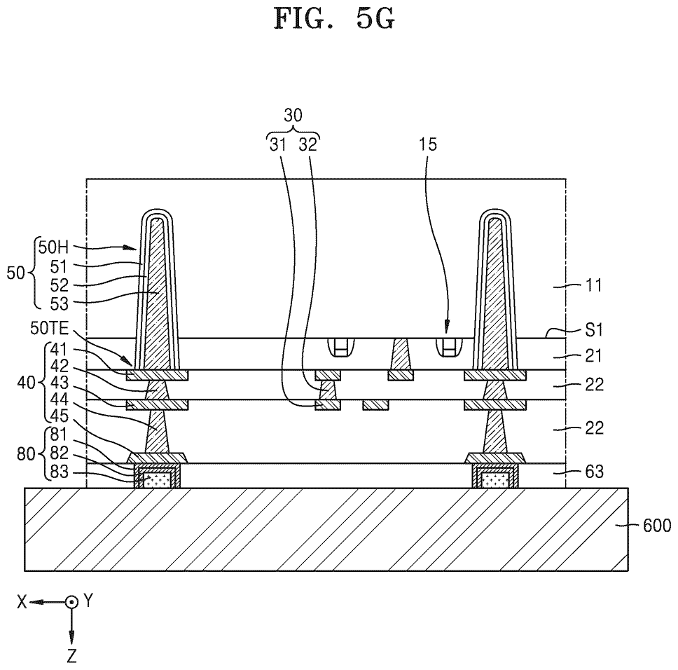

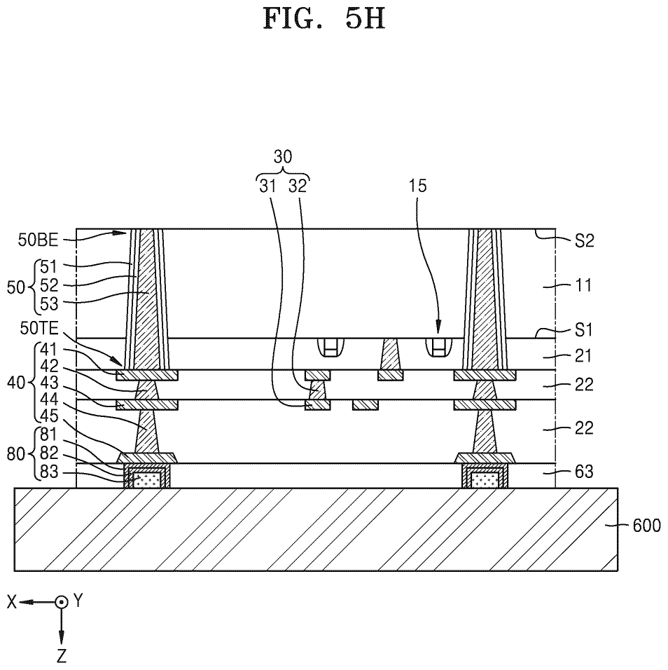

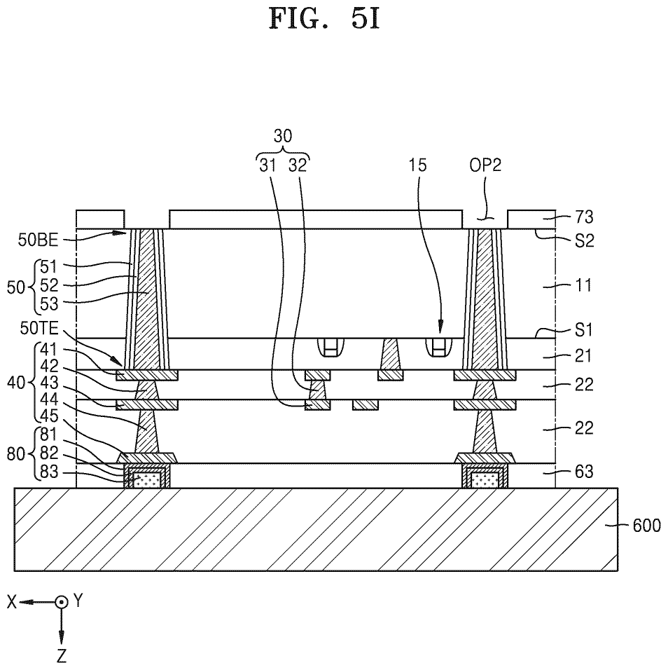

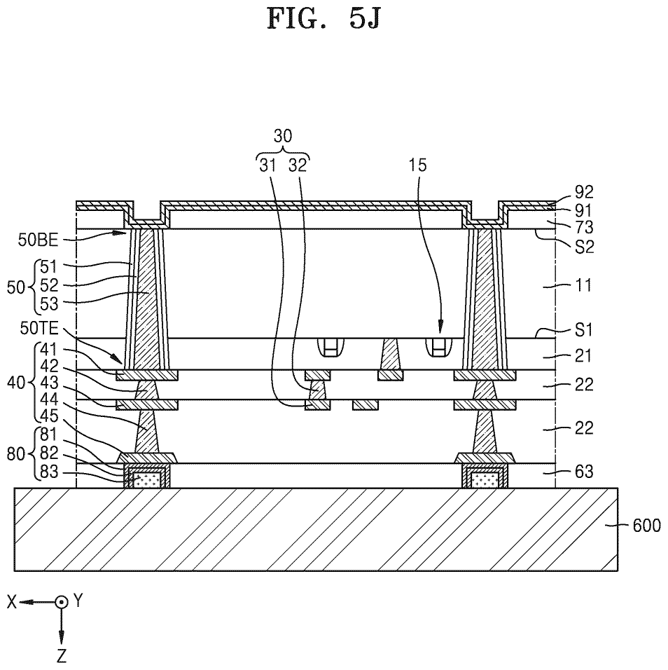

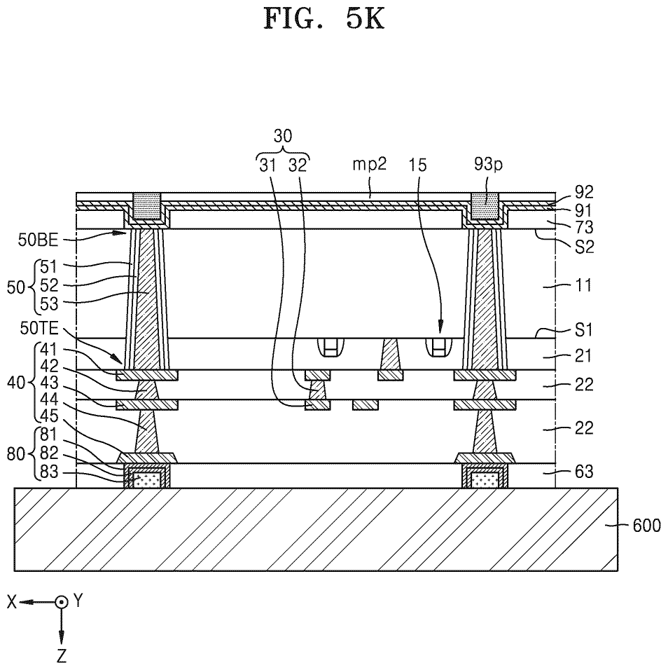

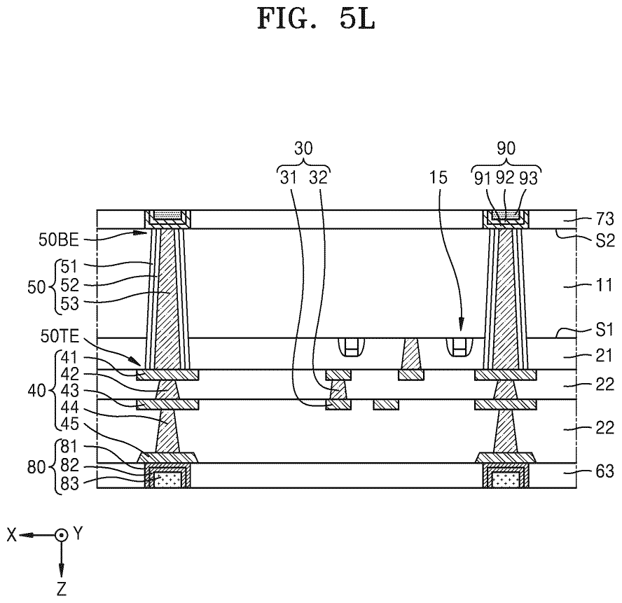

FIGS. 5A through 5L are cross-sectional views illustrating a method of manufacturing a semiconductor package, according to an example embodiment.

Referring to FIG. 5A, the method of manufacturing a semiconductor package according to an example embodiment may include preparing the substrate 11, forming a plurality of transistors 15 on the first surface S1 of the substrate 11, and forming the first interlayer insulating layer 21 covering the plurality of transistors 15. The substrate 11 may include one of a single crystalline silicon wafer, a SiGe wafer, and a silicon on insulator (SW) wafer. The first interlayer insulating layer 21 may include at least one of a silicon oxide (SiO) layer, a silicon carbonized oxide (SiCO) layer, a silicon nitride (SiN) layer, a silicon carbonized nitride (SiCN) layer, or other insulating material layer, which are formed by a deposition process.

Referring to FIG. 5B, a TSV structure 50 penetrating the first interlayer insulating layer 21 and the substrate 11 may be formed on the resultant product of FIG. 5A. A TSV hole 50H may be formed by performing an etching process on the first interlayer insulating layer 21 and the substrate 11. The TSV liner 51 may be conformally formed on the inner wall of the TSV hole 50H, the TSV barrier layer 52 may be conformally formed on the TSV liner 51, and the TSV plug 53 may be formed on the TSV barrier layer 52.

The TSV liner 51 may include silicon oxide formed by performing an atomic layered deposition (ALD) process, the TSV barrier layer 52 may include TiN or TaN, and the TSV plug 53 may include Cu. By using a chemical mechanical plating (CMP) process, the upper surface of the TSV structure 50 may be coplanar with the upper surface of the first interlayer insulating layer 21.

Referring to FIG. 5C, the internal circuit 30, the connecting circuit 40, the second interlayer insulating layer 22, and the first passivation layer 63 may be formed on the resultant product of FIG. 5B. The internal circuit 30 may include the internal wirings 31, which horizontally extend, and the multi-layered internal vias 32, which vertically extend. The internal wirings 31 and the multi-layered internal vias 32 may be formed by using a photolithography process, an etching process, a deposition process, a plating process, and/or a planarization process. The internal circuit 30 may be electrically connected to the substrate 11 and the transistor 15.

The connecting circuit 40 may include the lower TSV pad 41, the TSV connecting wiring 43, the lower TSV connecting via 42, the upper TSV connecting via 44, and the upper TSV pad 45, which are formed by using a photolithography process, an etching process, a deposition process, a plating process, and/or a planarization process. The upper TSV pad 45 may include the TSV I/O pad. The lower TSV pad 41 may be formed on the first interlayer insulating layer 21 to be in contact with the upper end 50TE of the TSV structure 50. The TSV connecting wiring 43 may be arranged at the same vertical level as one layer of the internal wirings 31. The upper TSV pad 45 may be arranged at the highest vertical level of the internal circuit 30 and the connecting circuit 40. The lower TSV connecting via 42 may electrically connect the lower TSV pad 41 to the TSV connecting wiring 43, and the upper TSV connecting via 44 may electrically connect the TSV connecting wiring 43 to the upper TSV pad 45.

The internal circuit 30 and the connecting circuit 40 may include a conductor. For example, the internal circuit 30 and the connecting circuit 40 may include metal (e.g., W, Cu, Al, Ni, or Ti), a metal compound (e.g., TiN or WN), or metal silicide (e.g., TiSi, WSi, CoSi, or NiSi). In another example embodiment, the upper TSV pad 45 may include aluminum to allow a probe or the like of a test facility to be in contact therewith.

The second interlayer insulating layer 22 may include at least one of SiO layer, a SiCO layer, a SiN layer, a SiCN layer, or other insulating material layer. The first passivation layer 63 may be arranged on the second interlayer insulating layer 22. The first passivation layer 63 may include a first opening OP1 exposing a surface of the upper TSV pad 45. The first passivation layer 63 may include silicon nitride, polyimide, or a combination thereof.

Referring to FIG. 5D, the first barrier layer 81 and the first seed layer 82 may be conformally formed on the upper TSV pad 45 exposed in the first passivation layer 63 and the first opening OP1.

The first barrier layer 81 and the first seed layer 82 may be formed by performing a physical vapor deposition (PVD) process including sputtering or a metal organic CVD (MOCVD) process. The first barrier layer 81 may include TiN or TaN. The first seed layer 82 may include at least one of Ti, Cu, Ni, W, or alloys thereof, for example, TiNi, and TiW. In another example embodiment, the first barrier layer 81 and the first seed layer 82 may be formed as a single layer.

Referring to FIG. 5E, a first mask pattern mp1 may be formed on the first seed layer 82, and a preliminary first pad plug 83p may be formed by performing a plating process. The first mask pattern mp1 may include a photoresist. The preliminary first pad plug 83p may include Cu or Ni.

Referring to FIG. 5F, from the resultant product of FIG. 5E, the first seed layer 82 may be exposed by removing the first mask pattern mp1. The first mask pattern mp1 may be removed by using an ashing process using oxygen (02) plasma or a strip process such as a sulfuric acid boil.

Thereafter, the first bumping pad 80 may be formed by removing the first seed layer 82 exposed to the uppermost surface of the first passivation layer 63 and the first barrier layer 81 thereunder. Removing the first seed layer 82 and the first barrier layer 81 may include performing a wet process. In the wet process, the first seed layer 82 and the first barrier layer 81 may be excessively removed, and an under-cut may occur under the first pad plug 83. The under-cut is omitted in the drawing. At least a portion of the preliminary first pad plug (83p in FIG. 5E) may be removed by using a CMP process to form the first pad plug 83. The first passivation layer 63 may be used as a CMP stopping layer. For example, an upper surface of the first passivation layer 63 may be coplanar with the upper surface of the first bumping pad 80.

Referring to FIG. 5G, a support carrier 600 may be attached to the upper surface of the first passivation layer 63 by inverting the resultant product of FIG. 5F.

Referring to FIG. 5H, the lower end 50BE of the TSV structure 50 may be exposed by recessing the second surface S2 of the substrate 11. The recessing of the second surface S2 of the substrate 11 may include performing a silicon etching process.

Referring to FIG. 5I, the second passivation layer 73 may be formed on the second surface S2 of the substrate 11. The second passivation layer 73 may include silicon nitride, polyimide, or a combination thereof. The second passivation layer 73 may include a second opening OP2 exposing a surface of the lower end 50BE of the TSV structure 50.

Referring to FIG. 5J, the second barrier layer 91 and the second seed layer 92 may be conformally formed on the lower end 50BE of the TSV structure 50 exposed in the second passivation layer 73 and on the second opening OP2. Materials of the second barrier layer 91 and the second seed layer 92 may be different from materials of the first barrier layer 81 and the first seed layer 82, respectively. For example, the second seed layer 92 may include a material having lower reactivity than the first seed layer 82. For example, reactivity to water of the first seed layer 82 and reactivity to water of the second seed layer 92 may be different from each other. For example, the first seed layer 82 may include Ta, and the second seed layer 92 may include Ti. The inventive concepts are not limited thereto, and the material included in the first seed layer 82 and the material included in the second seed layer 92 may be variously modified. Each of the second barrier layer 91 and the second seed layer 92 may be formed by using a process that is the same as or substantially similar to a process applied to each of the first barrier layer 81 and the first seed layer 82.

Referring to FIG. 5K, a second mask pattern mp2 may be formed on the second seed layer 92, and a preliminary second pad plug 93p may be formed by performing a plating process. The second mask pattern mp2 may include a photoresist. The preliminary second pad plug 93p may include Cu or Ni.

Referring to FIG. 5L, from the resultant product of FIG. 5K, the second seed layer 92 may be exposed by removing the second mask pattern mp2. The second mask pattern mp2 may be removed by using an ashing process using O₂ plasma or a strip process such as a sulfuric acid boil.

Thereafter, the second bumping pad 90 may be formed by removing the second seed layer 92 exposed on the second passivation layer 73 and the second barrier layer 91 under the second seed layer 92. Removing the second seed layer 92 and the second barrier layer 91 may include performing a wet process. In the wet process, the second barrier layer 91 and the second seed layer 92 may be excessively removed, and an under-cut may occur under the second pad plug 93. The under-cut is omitted in the drawing. At least a portion of the preliminary second pad plug (93p in FIG. 5K) may be removed by a CMP process, and the second pad plug 93 may be formed. The second passivation layer 73 may be used as a CMP stopping layer. For example, the lower surface of the second passivation layer 73 may be coplanar with the lower surface of the second bumping pad 90. Thereafter, the support carrier 600 may be removed, and the semiconductor package 10 may be formed.

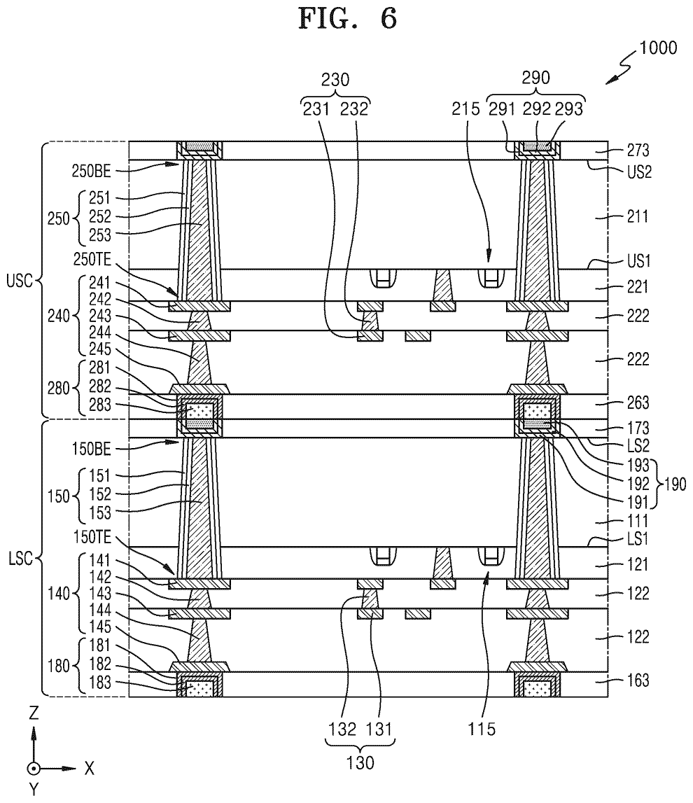

FIG. 6 is a cross-sectional view of a semiconductor package 1000 according to an example embodiment.

Referring to FIG. 6, the semiconductor package 1000 may include a lower semiconductor package LSC and an upper semiconductor package USC. The lower semiconductor package LSC may include a lower transistor 115 arranged on a lower first surface LS1 of a lower substrate 111, a lower internal circuit 130, a lower connecting circuit 140, a lower first interlayer insulating layer 121, a lower second interlayer insulating layer 122, a lower TSV structure 150 penetrating the lower substrate 111 and the lower first interlayer insulating layer 121, a lower first bumping pad 180 arranged on the lower first surface LS1 of the lower substrate 111 to be vertically aligned with the lower TSV structure 150, and a lower second bumping pad 190 arranged on a lower second surface LS2 of the lower substrate 111 to be aligned with the lower TSV structure 150 in the vertical direction (Z direction).

The upper semiconductor package USC may include an upper transistor 215 arranged on an upper first surface US1 of an upper substrate 211, an upper internal circuit 230, an upper connecting circuit 240, an upper first interlayer insulating layer 221, an upper second interlayer insulating layer 222, an upper TSV structure 250 penetrating the upper substrate 211 and the upper first interlayer insulating layer 221, an upper first bumping pad 280 arranged on an upper first surface US1 of the upper substrate 211 to be vertically aligned with the upper TSV structure 250, and an upper second bumping pad 290 arranged on an upper second surface US2 of the upper substrate 211 to be aligned with the upper TSV structure 250 in the vertical direction (Z direction).

The lower substrate 111 and the upper substrate 211 may be the same as or substantially similar to the substrate 11 in FIG. 1, and the lower transistor 115 and the upper transistor 215 may be the same as or substantially similar to the transistor 15 in FIG. 1. The lower internal circuit 130 and the upper internal circuit 230 may be the same as or substantially similar to the internal circuit 30 in FIG. 1, and the lower connecting circuit 140 and the upper connecting circuit 240 may be the same as or substantially similar to the connecting circuit 40 in FIG. 1. The lower first interlayer insulating layer 121 and the upper first interlayer insulating layer 221 may be the same as or substantially similar to the first interlayer insulating layer 21 in FIG. 1, and the lower second interlayer insulating layer 122 and the upper second interlayer insulating layer 222 may be the same as or substantially similar to the second interlayer insulating layer 22 in FIG. 1. In addition, the lower TSV structure 150 and the upper TSV structure 250 may be the same as or substantially similar to the TSV structure 50 in FIG. 1, the lower first bumping pad 180 and the upper first bumping pad 280 may be the same as or substantially similar to the first bumping pad 80 in FIG. 1, and the lower second bumping pad 190 and the upper second bumping pad 290 may be the same as or substantially similar to the second bumping pad 90 in FIG. 1.

The lower semiconductor package LSC may directly contact and be electrically connected to the upper semiconductor package USC. For example, the lower second bumping pad 190 of the lower semiconductor package LSC may be in direct contact with and electrically connected to the upper first bumping pad 280 of the upper semiconductor package USC. Further, a lower second passivation layer 173 of the lower semiconductor package LSC may contact an upper first passivation layer 263 of the upper semiconductor package USC.

When the lower semiconductor package LSC directly contacts and is electrically connected to the upper semiconductor package USC, water may be generated as a by-product. The generated water may be absorbed into the lower second bumping pad 190 of the lower semiconductor package LSC and the upper first bumping pad 280 of the upper semiconductor package USC. Because the density of the lower second passivation layer 173 is less than that of the upper first passivation layer 263, the generated water may move relatively further to the lower second passivation layer 173. Accordingly, the reactivity to water of a lower second seed layer 192 of the lower second bumping pad 190 arranged in the lower second passivation layer 173 may be less than that of the upper first bumping pad 280 arranged in the upper first passivation layer 263.

For example, the semiconductor package 1000 may constitute a high bandwidth memory (HBM). In another example embodiment, the semiconductor package 1000 may be a portion of a 2.5-dimensional stacked structure and/or a portion of a three-dimensional stacked structure.

In a general semiconductor package, when a first seed layer and a second seed layer include the same material, are directly in contact with each other, and electrically connected to each other, water, that is a by-product of a process, penetrates into the second seed layer, and accordingly, the reliability of the semiconductor package may be relatively low.

In the semiconductor package 1000, the lower second seed layer 192 of the lower semiconductor package LSC and an upper first seed layer 282 of the upper semiconductor package USC may include different materials from each other. The lower second seed layer 192 of the lower semiconductor package LSC may include a material having a lower reactivity to water than the material included in the upper first seed layer 282 of the upper semiconductor package USC. Accordingly, water generated in a bonding process of the lower semiconductor package LSC and the upper semiconductor package USC may move relatively further to the lower second seed layer 192 of the lower semiconductor package LSC having low reactivity to water, and thus, reliability of the semiconductor package 1000 according to some example embodiments of the inventive concepts may be relatively high.

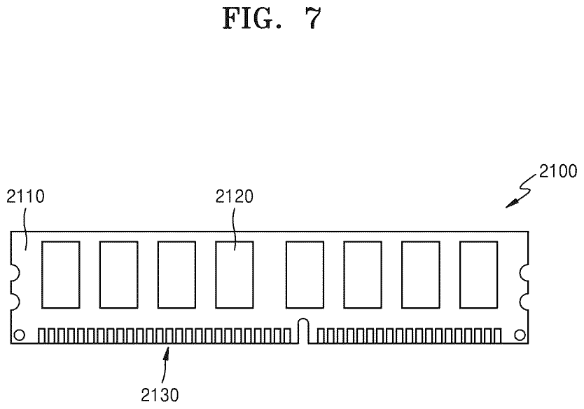

FIG. 7 is a conceptual diagram of a memory module 2100 according to an example embodiment.

Referring to FIG. 7, the memory module 2100 may include a module substrate 2110, a plurality of memory devices 2120 arranged on the memory module 2100, and a plurality of terminals 2130 arranged on one side of the module substrate 2110. The module substrate 2110 may include a PCB. The plurality of memory devices 2120 may include at least one of the semiconductor packages 10, 10a, and 1000, according to some example embodiments. The plurality of terminals 2130 may include a metal such as Cu. The plurality of terminals 2130 may be and electrically connected to the memory devices 2120, respectively.

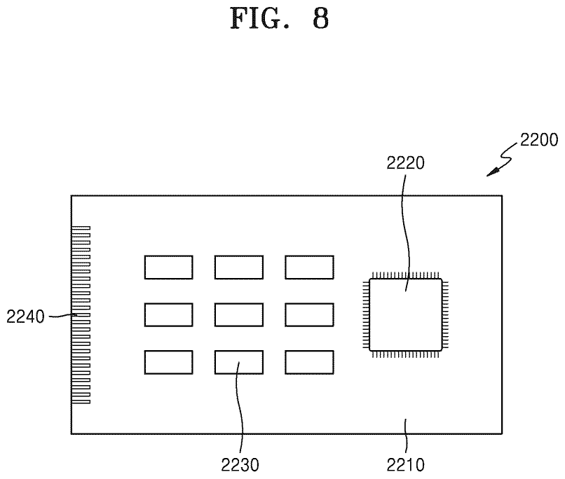

FIG. 8 is a conceptual diagram of a semiconductor module 2200 according to an example embodiment.

Referring to FIG. 8, the semiconductor module 2200 may include a processor 2220 mounted on the module substrate 2210 and semiconductor packages 2230. The processor 2220 or the semiconductor packages 2230 may include at least one of the semiconductor packages 10, 10a, and 1000 according to the above example embodiments. Conductive input/output terminals 2240 may be arranged on at least one side of the module substrate 2210.

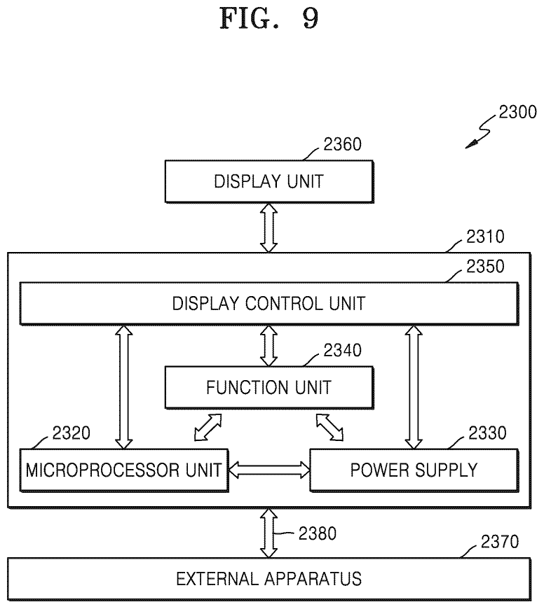

FIG. 9 is a conceptual diagram of an electronic system 2300 according to an example embodiment.

Referring to FIG. 9, the electronic system 2300 may include a body 2310, a display unit 2360, an external device 2370, and a bus 2380. The body 2310 may include a microprocessor unit 2320, a power supply unit 2330, a function unit 2340 and/or a display control unit 2350. The body 2310 may include a system board or a mother board including a PCB or the like, and/or a case. The microprocessor unit 2320, the power supply unit 2330, the function unit 2340, and the display control unit 2350 may be mounted or arranged on or inside an upper surface of the body 2310. The display unit 2360 may be arranged on the upper surface of the body 2310 or inside/outside the body 2310. The display unit 2360 may display an image processed by the display control unit 2350. For example, the display unit 2360 may include a liquid crystal display (LCD), an active matrix organic light-emitted diode (AMOLED), or various display panels. The display unit 2360 may include a touch screen. Accordingly, the display unit 2360 may have an input/output function. The power supply unit 2330 may supply a current or voltage to the microprocessor unit 2320, the function unit 2340, the display control unit 2350, etc. The power supply unit 2330 may include a charging battery, a battery socket, and/or a voltage/current converter. The microprocessor unit 2320 may receive a voltage from the power supply unit 2330, and control the function unit 2340 and the display unit 2360. For example, the microprocessor unit 2320 may include a CPU or an application processor (AP). The function unit 2340 may include a touch pad, a touch screen, a volatile/non-volatile memory, a memory card controller, a camera, a light, a voice and video playback processor, a wireless transceiver antenna, a speaker, a micro phone, a USB port, and other units having various functions. The microprocessor unit 2320 or the function unit 2340 may include at least one of the semiconductor packages 10, 10a, and 1000 according to the above example embodiments.

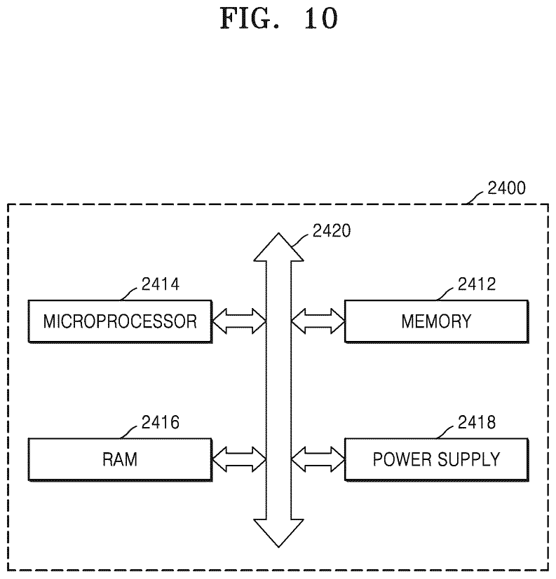

FIG. 10 is a conceptual diagram of an electronic system 2400 according to an example embodiment.

Referring to FIG. 10, the electronic system 2400 may include a microprocessor 2414 performing data communication via a bus 2420, a memory 2412 and a user interface 2418. The microprocessor 2414 may include a CPU or an AP. The electronic system 2400 may further include RAM 2416 directly communicating with the microprocessor 2414. The microprocessor 2414 and/or the RAM 2416 may be assembled in a single package. The user interface 2418 may be used to input information to the electronic system 2400 or to output information from the electronic system 2400. For example, the user interface 2418 may include a touch pad, a touch screen, a keyboard, a mouse, a scanner, a voice detector, a cathode ray tube (CRT) monitor, a LCD, an AMOLED, a plasma display panels (PDP), a printer, a light, or other various input/output devices. The memory 2412 may store operation codes of the microprocessor 2414, data processed by the microprocessor 2414, or external input data. The memory 2412 may include a memory controller, a hard disk, or a solid state drive (SSD). The microprocessor 2414, the RAM 2416, and/or the memory 2412 may include at least one of the semiconductor packages 10, 10a, and 1000 according to some example embodiments of the inventive concepts.

Any functional blocks shown in the figures and described above may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a substrate including a first surface and a second surface opposite to the first surface;
a connecting circuit on the first surface of the substrate;
a through silicon via (TSV) structure penetrating the substrate;
a first passivation layer on the connecting circuit;
a second passivation layer on the second surface of the substrate;
a first bumping pad inside the first passivation layer; and
a second bumping pad inside the second passivation layer,
wherein the first bumping pad comprises,
a first pad plug, and
a first seed layer surrounding a lower surface and sidewalls of the first pad plug,
wherein the second bumping pad comprises,
a second pad plug, and
a second seed layer surrounding an upper surface and sidewalls of the second pad plug, and
wherein the first seed layer and the second seed layer comprise materials having different reactivities to water.

2. The semiconductor package of claim 1, wherein reactivity to water of the second seed layer is less than reactivity to water of the first seed layer.

3. The semiconductor package of claim 1, wherein
an upper surface of the first bumping pad is coplanar with an upper surface of the first passivation layer, and
a lower surface of the second bumping pad is coplanar with a lower surface of the second passivation layer.

4. The semiconductor package of claim 1, wherein the first passivation layer comprises a different material from the second passivation layer.

5. The semiconductor package of claim 1, wherein a density of the first passivation layer is greater than a density of the second passivation layer.

6. The semiconductor package of claim 1, wherein
the first bumping pad further comprises a first barrier layer surrounding a lower surface and outer walls of the first seed layer, and
the first barrier layer contacts the connecting circuit.

7. The semiconductor package of claim 1, wherein
the second bumping pad further comprises a second barrier layer surrounding an upper surface and outer walls of the second seed layer, and
the second barrier layer contacts the TSV structure.

8. A semiconductor package comprising:
a substrate including a first surface and a second surface opposite to the first surface;
an interlayer insulating layer on the first surface of the substrate;
a through silicon via (TSV) structure penetrating the substrate and the interlayer insulating layer;
a connecting circuit on the interlayer insulating layer, the connecting circuit including a TSV connecting via that is electrically connected to the TSV structure;
a first passivation layer on the connecting circuit;
a second passivation layer on the second surface of the substrate;
a first bumping pad inside the first passivation layer; and
a second bumping pad inside the second passivation layer,
wherein the first bumping pad includes,
a first pad plug,
a first seed layer surrounding a lower surface and sidewalls of the first pad plug, and
a first barrier layer surrounding a lower surface and outer walls of the first seed layer,
wherein the second bumping pad includes,
a second pad plug,
a second seed layer surrounding a lower surface and sidewalls of the second pad plug, and
a second barrier layer surrounding a lower surface and outer walls of the second seed layer, and
wherein reactivity to water of the second seed layer is less than reactivity to water of the first seed layer.

9. The semiconductor package of claim 8, wherein the first seed layer comprises tantalum (Ta), and the second seed layer comprises titanium (Ti).

10. The semiconductor package of claim 8, wherein resistance to a temperature of the first passivation layer is greater than resistance to a temperature of the second passivation layer.

11. The semiconductor package of claim 8, wherein the first pad plug and the second pad plug comprise an identical material.

12. The semiconductor package of claim 8, wherein each of a lower surface of the first bumping pad and an upper surface of the second bumping pad has a flat shape.

13. The semiconductor package of claim 8, wherein the first barrier layer and the second barrier layer comprise different materials from each other.

14. The semiconductor package of claim 8, wherein
the first seed layer and the first barrier layer comprise an identical material, or
the second seed layer and the second barrier layer comprise an identical material.

15. The semiconductor package of claim 8, comprising:
a transistor on the first surface of the substrate; and
an internal wiring and an internal via in the interlayer insulating layer,
wherein the internal via is electrically connected to the substrate or the transistor.

16. A semiconductor package comprising:
a substrate including a first surface and a second surface opposite to the first surface;
a transistor on the first surface of the substrate;
an interlayer insulating layer on the first surface of the substrate, and covering the transistor;
a through silicon via (TSV) structure penetrating the substrate and the interlayer insulating layer;
a connecting circuit on the interlayer insulating layer, the connecting circuit including a TSV connecting via that is electrically connected to the TSV structure;
a first passivation layer on the connecting circuit;
a second passivation layer on the second surface of the substrate;
a first bumping pad inside the first passivation layer; and
a second bumping pad inside the second passivation layer,
wherein the first bumping pad includes,
a first pad plug,
a first seed layer surrounding a lower surface and sidewalls of the first pad plug, and
a first barrier layer surrounding a lower surface and outer walls of the first seed layer,
wherein the second bumping pad includes,
a second pad plug,
a second seed layer surrounding a lower surface and sidewalls of the second pad plug, and
a second barrier layer surrounding a lower surface and outer walls of the second seed layer,
wherein the first seed layer and the second seed layer comprise different materials, and
wherein reactivity to water of the second seed layer is less than reactivity to water of the first seed layer.

17. The semiconductor package of claim 16, wherein the reactivity to water of the first barrier layer is greater than the reactivity to water of the second barrier layer.

18. The semiconductor package of claim 16, wherein the first seed layer or the first barrier layer comprises tantalum (Ta), and the second seed layer or the second barrier layer comprises titanium (Ti).

19. The semiconductor package of claim 16, wherein
a range of a horizontal width of the first bumping pad or the second bumping pad is 2 micrometers to 10 micrometers,
a range of a vertical thickness of the first bumping pad is 0.3 micrometers to 3 micrometers, and
a range of a vertical thickness of the second bumping pad is 0.2 micrometers to 2 micrometers.

20. The semiconductor package of claim 16, wherein
the connecting circuit comprises,
a lower TSV pad contacting the TSV structure on the interlayer insulating layer,
a lower TSV connecting via on the lower TSV pad,
a TSV connecting wiring on the lower TSV connecting via,
an upper TSV connecting via on the TSV connecting wiring and in contact with the TSV connecting wiring, and
an upper TSV pad on the upper TSV connecting via, and
an upper surface of the upper TSV pad contacts a lower surface of the first bumping pad.
